(19) United States
(12) Patent Application Publication
(10) Pub. No.: US 2026/0096151 A1
(43) Pub. Date: Apr. 2, 2026

(54) THIN FILM TRANSISTOR AND DISPLAY APPARATUS COMPRISING THE SAME

(71) Applicant: LG Display Co., Ltd., Seoul (KR)

(72) Inventors: Dongyeon KANG, Paju-si (KR); Jaeyoon PARK, Paju-si (KR); Hyeonjoo SEUL, Paju-si (KR)

(73) Assignee: LG Display Co., Ltd., Seoul (KR)

(21) Appl. No.: 19/305,519

(22) Filed: Aug. 20, 2025

(30) Foreign Application Priority Data
Sep. 30, 2024 (KR) 10-2024-0133001

(51) Int. Cl. H10D 30/67; H10K 59/121

(52) U.S. Cl. CPC H10D 30/6755; H10D 30/6757; H10K 59/1213

(57) ABSTRACT

The present disclosure provides a thin film transistor including an active layer; a gate electrode disposed on the active layer and overlapping at least a portion of the active layer; and a hydrogen capture layer disposed on the gate electrode. The active layer includes a channel portion and first and second connecting portions on respective sides of the channel portion. The hydrogen capture layer includes first and second capture patterns spaced apart, wherein portions of each capture pattern overlap the gate electrode in a plan view.

### CROSS-REFERENCE TO RELATED APPLICATIONS

This application claims the benefit of priority of the Korean Patent Application No. 10-2024-0133001 filed on Sep. 30, 2024, which is hereby incorporated by reference as if fully set forth herein.

### BACKGROUND

### Technical Field

The present disclosure relates to a thin film transistor and a display apparatus including the same.

### Description of the Related Art

Thin film transistors are widely used as switching devices or driving devices in the field of electronic devices. In particular, since thin film transistors can be manufactured on glass substrates or plastic substrates, they are widely used as switching devices in display apparatuses such as liquid crystal display apparatuses or organic light emitting devices.

Thin film transistors can be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Oxide semiconductor thin film transistors can easily obtain desired properties because the oxide constituting the active layer can be formed at a relatively low temperature, have high mobility, and have a large resistance change depending on the oxygen content. In addition, because oxide semiconductors are transparent due to the characteristics of oxides, they are also advantageous in implementing transparent displays.

### BRIEF SUMMARY

In oxide semiconductors, an increase in the width of the active layer may lead to a greater depth of conductorization penetration. This can reduce the effective channel length and adversely affect the operational stability of the thin film transistor. Accordingly, the present disclosure provides embodiments that address and control the depth of conductorization penetration.

Various embodiments of the disclosed thin film transistor include a hydrogen capture layer disposed above the gate electrode. The hydrogen capture layer comprises patterned regions configured to trap hydrogen and reduce its diffusion into the active layer. These capture patterns are positioned to overlap both the gate electrode and the connecting portions of the active layer, which helps to stabilize the threshold voltage by limiting conductorization near the channel boundaries. The hydrogen capture layer includes regions of different thicknesses, where thinner etched areas increase surface area and defect density to improve hydrogen trapping effectiveness.

Each capture pattern may be divided into multiple sub-patterns with specific minimum widths and separations to maintain electrical conductivity while enhancing hydrogen absorption. Additional patterns may be placed in regions that do not overlap the gate electrode, providing further suppression of hydrogen diffusion near the electrode contact areas. These structural features can be applied in display devices, including those with organic light emitting diodes and gate driver circuits, to improve reliability and performance in environments where hydrogen exposure is a concern.

One embodiment of the present disclosure is to provide a thin film transistor that suppresses or prevents hydrogen from diffusing into an active layer by having a hydrogen capture layer including a large amount of traps capable of capturing hydrogen.

One embodiment of the present disclosure is to provide a thin film transistor in which conductorization penetration into a channel portion is controlled by having a hydrogen capture layer including a large number of traps capable of trapping hydrogen.

One embodiment of the present disclosure is to provide a thin film transistor having improved reliability by having a hydrogen capture layer including a large number of traps capable of capturing hydrogen.

Another embodiment of the present disclosure is to provide a display apparatus including such a thin film transistor.

One embodiment of the present disclosure for achieving the above-described technical problem is to provide a thin film transistor including an active layer; a gate electrode disposed on the active layer and overlapping at least a portion of the active layer; and a hydrogen capture layer disposed on the gate electrode, wherein the active layer includes a channel portion; a first connecting portion connected to one side of the channel portion; and a second connecting portion connected to the other side of the channel portion, and the hydrogen capture layer includes a first capture pattern and a second capture pattern that are spaced apart from each other, and at least a portion of the first capture pattern and at least a portion of the second capture pattern overlap the gate electrode in a plan view, respectively.

At least a portion of the first capture pattern may overlap the first connecting portion in a plan view, and at least a portion of the second capture pattern may overlap the second connecting portion in a plan view.

The hydrogen capture layer may include any one of an IGZO (InGaZnO)-based oxide semiconductor material, in which a concentration of Ga is 40% or more relative to the total concentration of In, Ga, and Zn based on the number of atoms, a GO (GaO)-based oxide semiconductor material, a GZO (GaZnO)-based oxide semiconductor material, and silicon oxide (SiO₂).

The first capture pattern and the second capture pattern can be disposed in a groove of the hydrogen capture layer.

Hydrogen traps that bind to hydrogen may exist on the surfaces of the first capture pattern and the second capture pattern.

When the region of the hydrogen capture layer in which the first capture pattern or the second capture pattern is disposed is referred to as a first region, and the region of the hydrogen capture layer in which the first capture pattern or the second capture pattern is not disposed is referred to as a second region, the thickness of the first region may be thinner than the thickness of the second region.

The thickness of the second region may be 10 nm or less, and the thickness of the first region may be 20% to 60% of the thickness of the second region.

When the direction parallel to the shortest line connecting the first connecting portion and the second connecting portion is referred to as the first direction, and the direction perpendicular to the first direction is referred to as the second direction, the first capture pattern and the second capture pattern can each have a width of 2 μm or more based on the second direction.

The thin film transistor further includes an insulating film disposed on the hydrogen capture layer, wherein the hydrogen capture layer is disposed between the active layer and the insulating film, and the insulating film can be in contact with the first capture pattern and the second capture pattern.

The insulating film may include at least one of silicon nitride (SiNx), silicon oxide (SiO₂), and aluminum oxide (Al₂O₃).

The first capture pattern and the second capture pattern may each include a first sub-capture pattern and a second sub-capture pattern that are spaced apart from each other.

When a direction parallel to a shortest line connecting the first connecting portion and the second connecting portion is referred to as a first direction, and a direction perpendicular to the first direction is referred to as a second direction, the first sub-capture pattern and the second sub-capture pattern of the first capture pattern may have a gap of 2 μm or more based on the second direction, and the first sub-capture pattern and the second sub-capture pattern of the second capture pattern may have a gap of 2 μm or more based on the second direction.

The hydrogen capture layer further includes a third capture pattern and a fourth capture pattern that do not overlap the gate electrode in a plan view, wherein the third capture pattern may be disposed closer to the first connecting portion than to the second connecting portion, and the fourth capture pattern may be disposed closer to the second connecting portion than to the first connecting portion.

The third capture pattern and the fourth capture pattern may each include a first sub-capture pattern and a second sub-capture pattern that are spaced apart from each other.

Another embodiment of the present disclosure provides a display apparatus including the thin film transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a plan view of a thin film transistor according to one embodiment of the present disclosure.

FIG. 2 is a cross-sectional view taken along line I-I′ of FIG. 1.

FIG. 3 is a cross-sectional view taken along line II-II′ of FIG. 1.

FIGS. 4A and 4B are exploded perspective views of thin film transistors according to comparative examples and embodiments.

FIG. 5 is a drawing showing the appearance of the hydrogen capture layer of the present disclosure.

FIG. 6 is a plan view of a thin film transistor according to another embodiment of the present disclosure.

FIG. 7 is a plan view of a thin film transistor according to another embodiment of the present disclosure.

FIG. 8 is a plan view of a thin film transistor according to another embodiment of the present disclosure.

FIG. 9 is a schematic diagram of a display apparatus according to one embodiment of the present disclosure.

FIG. 10 is a circuit diagram for one pixel of FIG. 9.

FIG. 11 is a plan view of the pixels of FIG. 10.

FIG. 12 is a cross-sectional view taken along line III-III′ of FIG. 11.

### DETAILED DESCRIPTION

Advantages and features of the present disclosure and implementation methods thereof will be clarified through the following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath”may include “below or beneath”and “above”orientations.

Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just”or “direct”is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

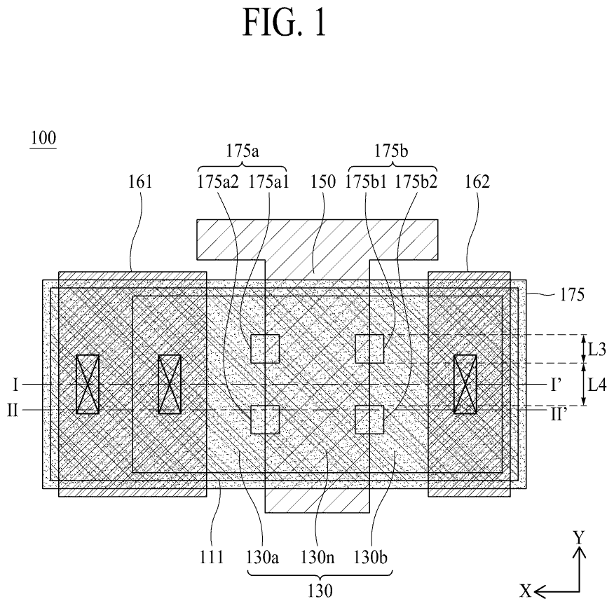

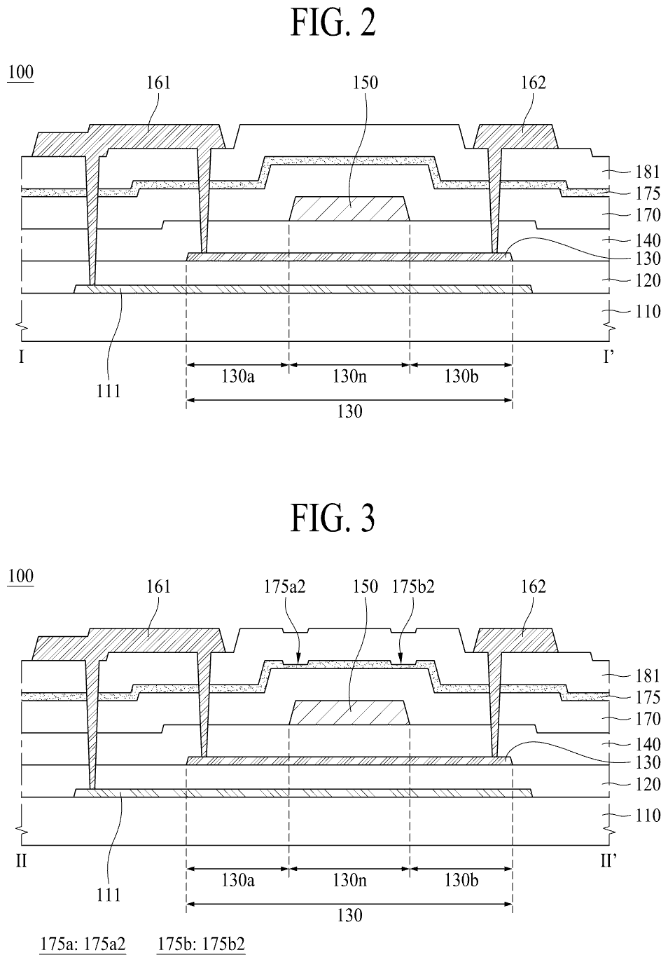

FIG. 1 is a plan view of a thin film transistor (100) according to one embodiment of the present disclosure. FIG. 2 is a cross-sectional view taken along line I-I′ of FIG. 1. FIG. 3 is a cross-sectional view taken along line II-II′ of FIG. 1.

Specifically, referring to FIGS. 1 to 3, the thin film transistor (100) includes a base substrate (110), a buffer layer (120), an active layer (130), a gate insulating film (140), a gate electrode (150), an interlayer insulating film (170), a hydrogen control layer (175) (also referred to as ‘a hydrogen capture layer’), an insulating film (181), a source electrode (161), and a drain electrode (162).

Hereinafter, components of a thin film transistor (100) according to one embodiment of the present disclosure will be described in more detail.

The base substrate (110) may be made of glass or plastic. A transparent plastic having flexible properties, such as polyimide, may be used.

When polyimide is used as the base substrate (110), considering that a high-temperature deposition process is performed on the base substrate (110), a heat-resistant polyimide that can withstand high temperatures can be used. In this case, for forming a thin film transistor, processes such as deposition and etching can be performed while the polyimide substrate is disposed on a carrier substrate made of a highly durable material such as glass.

Referring to FIGS. 2 and 3, a buffer layer (120) may be disposed on a base substrate (110).

The buffer layer (120) is formed on the base substrate (110) and may be formed of an inorganic material or an organic material. For example, it may include an insulating oxide such as silicon oxide (SiOx) or aluminum oxide (Al₂O₃).

The buffer layer (120) protects the active layer (130) by blocking impurities such as moisture and oxygen flowing in from the base substrate (110) and serves to flatten the upper portion of the base substrate (110), and can be formed as a single layer or multiple layers.

Referring to FIGS. 2 and 3, an active layer (130) may be disposed on a buffer layer (120).

The active layer (130) may include a channel portion (130n), a first connecting portion (130a), and a second connecting portion (130b).

The channel portion (130n) overlaps with the gate electrode (150). The channel portion (130n) acts as a channel of the thin film transistor (100).

Specifically, the active layer (130) may include a channel portion (130n) that overlaps at least a portion of the gate electrode (150) in a plan view, a first connecting portion (130a) that does not overlap the gate electrode (150) in a plan view and is connected to one side of the channel portion (130n), and a second connecting portion (130b) that does not overlap the gate electrode (150) in a plan view and is connected to the other side of the channel portion (130n).

According to one embodiment of the present disclosure, the first connecting portion (130a) and the second connecting portion (130b) are spaced apart from each other with the channel portion (130n) therebetween.

According to one embodiment of the present disclosure, the active layer (130) may be formed of a semiconductor material. The active layer (130) may include an oxide semiconductor material.

The oxide semiconductor material may include, for example, at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, one embodiment of the present disclosure is not limited thereto, and the active layer (130) may be made of other oxide semiconductor materials known in the art.

The first connecting portion (130a) and the second connecting portion (130b) can be formed by selectively conductorizing for the active layer (130) made of a semiconductor material. According to one embodiment of the present disclosure, selectively conductorization means imparting conductivity to a specific portion of the active layer (130) so that it can function like a conductor. A portion that is imparted conductivity by selective conductorization becomes conductive, and a portion that is not imparted conductivity does not become conductive.

According to one embodiment of the present disclosure, selective conductorization can be achieved by doping using a dopant or plasma treatment.

For example, selective conductorization for the active layer (130) may be achieved by dopant doping using a gate electrode (150), a metal layer, or a photoresist pattern as a mask. According to one embodiment of the present disclosure, implanting a dopant or dopant ion into a selected region of the active layer (130) is referred to as dopant doping. The dopant may include, for example, at least one of boron (B), phosphorus (P), fluorine (F), and hydrogen (H).

When selective conductorization is achieved for the active layer (130) by dopant doping, a region of the active layer (130) doped with a dopant is selectively conductorized and becomes a first connecting portion (130a) or a second connecting portion (130b). A region of the active layer (130) not doped with a dopant is not conductorized and can become a channel portion (130n).

In addition, selective conductorization of the active layer (130) may be achieved by plasma treatment applied in the process of patterning the gate insulating film (140). For example, plasma may be used in the process of patterning the gate insulating film (140), and a portion of the active layer (130) that comes into contact with the plasma may be selectively conductorized and may become a first connecting portion (130a) or a second connecting portion (130b). A portion of the active layer (130) that is protected by the gate insulating film (140) and does not come into contact with the plasma may not be conductorized and may become a channel portion (130n).

However, one embodiment of the present disclosure is not limited thereto, and the active layer (130) may be selectively made conductorized by other methods known in the art.

Although the active layer (130) is configured as a single layer in FIGS. 1 to 3, the present disclosure is not limited thereto. The active layer (130) may have a single-film structure or a multi-layer structure.

A gate insulating film (140) is disposed on the active layer (130). The gate insulating film (140) protects the channel portion (130n).

The gate insulating film (140) has insulating properties. The gate insulating film (140) may include, for example, at least one of silicon oxide, silicon nitride, and metal oxide. The gate insulating film (140) may have a single film structure or a multilayer film structure.

Referring to FIGS. 2 and 3, the gate insulating film (140) may be disposed on the entire surface of the base substrate (110) without being patterned. However, one embodiment of the present disclosure is not limited thereto, and the gate insulating film (140) may have a patterned structure.

The gate electrode (150) is disposed on the gate insulating film (140). The gate electrode (150) overlaps the channel portion (130n) of the active layer (130).

The gate electrode (150) may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode (150) may also have a multilayer film structure including at least two conductive films each having different physical properties. For example, the gate electrode (150) may include at least one of molybdenum (Mo) and titanium (Ti).

According to one embodiment of the present disclosure, the gate insulating film (140) can be patterned by etching using the gate electrode (150) as a mask, and in this process, the active layer (130) can be selectively conductorized to form a first connecting portion (130a) and a second connecting portion (130b). Specifically, according to one embodiment of the present disclosure, a region of the active layer (130) that overlaps with the gate electrode (150) is not made conductive to become a channel portion (130n) having semiconductor characteristics, and a region that does not overlap with the gate electrode (150) is made conductive to become a first connecting portion (130a) and a second connecting portion (130b).

Referring to FIGS. 2 and 3, an interlayer insulating film (170) may be disposed on the gate electrode (150). The interlayer insulating film (170) may be made of an organic or inorganic insulating material. The interlayer insulating film (170) may also be formed of a composite film of an organic film and an inorganic film.

According to one embodiment of the present disclosure, the thin film transistor (100) may include a hydrogen capture layer (175) disposed on an interlayer insulating film (170).

Referring to FIGS. 1 to 3, the hydrogen capture layer (175) may be disposed on the entire upper surface of the interlayer insulating film (170). However, one embodiment of the present disclosure is not limited thereto, and may not be disposed on the entire upper surface of the interlayer insulating film (170).

According to one embodiment of the present disclosure, the hydrogen capture layer (175) is a sheet of oxide-based semiconductor material that may include any one of an IGZO (InGaZnO)-based oxide semiconductor material in which a concentration of Ga is 40% or more relative to the total concentration of In, Ga, and Zn based on the number of atoms, a GO (GaO)-based oxide semiconductor material, a GZO (GaZnO)-based oxide semiconductor material, and silicon oxide (SiO₂).

In order to suppress hydrogen diffusion into the oxide semiconductor active layer, which can lead to unwanted conductorization at the channel edges, negative shifts in threshold voltage, and reduced device stability, the thin film transistor includes a hydrogen capture layer above the gate electrode. This layer is patterned with etched regions that form voids with high surface area, each functioning as a hydrogen trapping site. By retaining hydrogen within these cavities before it reaches the active layer, the hydrogen capture layer preserves the effective channel length, stabilizes operational characteristics over time, and improves overall reliability.

According to one embodiment of the present disclosure, the hydrogen capture layer (175) includes a first capture pattern (175a) and a second capture pattern (175b).

Referring to FIG. 1 and FIG. 3, the first capture pattern (175a) and the second capture pattern (175b) are spaced apart from each other with the gate electrode (150) interposed therebetween in a plan view.

Referring to FIGS. 1 and 3, a first capture pattern (175a) and a second capture pattern (175b) in which a portion of the hydrogen capture layer (175) is etched are disposed within an area whose edge is defined by the hydrogen capture layer (175). According to one embodiment of the present disclosure, the first capture pattern (175a) and the second capture pattern (175b) are disposed within an area defined by the hydrogen capture layer (175) in a planar view. Specifically, the first capture pattern (175a) and the second capture pattern (175b) may be said to be an area formed by etching a portion of the hydrogen capture layer (175). More specifically, the first capture pattern (175a) and the second capture pattern (175b) mean an area in which a portion of the hydrogen capture layer (175) is removed, rather than an area in which the hydrogen capture layer (175) is completely removed. For example, the first capture pattern (175a) and the second capture pattern (175b) can be disposed in the grooves of the hydrogen capture layer (175). In some embodiments, the first capture pattern (175a) and the second capture pattern (175b) may each correspond to a recessed region formed in the hydrogen capture layer, and may be considered among a plurality of recessed regions configured to trap hydrogen.

According to one embodiment of the present disclosure, the first capture pattern (175a) and the second capture pattern (175b) are formed by etching a portion of the hydrogen capture layer (175) using an etchant.

According to one embodiment of the present disclosure, hydrofluoric acid (HF), hydrochloric acid (HCl), and oxalic acid may be used as the etchant. However, one embodiment of the present disclosure is not limited thereto, and an etchant capable of etching the hydrogen capture layer (175) may be used.

When a part of the hydrogen capture layer (175) is etched using an etchant, a void defect is likely to occur in the bonding structure of the hydrogen capture layer (175). According to the present disclosure, the void defect of the hydrogen capture layer (175) is called a ‘hydrogen trap’.

In other words, when a part of the hydrogen capture layer (175) is etched using an etchant to form a first capture pattern (175a) and a second capture pattern (175b), a hydrogen trap that binds to hydrogen is formed on the surfaces of the first capture pattern (175a) and the second capture pattern (175b).

Specifically, when a portion of the hydrogen capture layer (175) is etched using an etchant, the surface area of the first capture pattern (175a) and the second capture pattern (175b) increases, so that a large number of hydrogen traps that bind to hydrogen may exist.

Due to this, the first capture pattern (175a) and the second hydrogen pattern (175b) of the hydrogen capture layer (175) can block or capture hydrogen supplied or diffused from the outside.

As a result, the reliability of the thin film transistor (100) can be improved. That is, unstable oxygen in the active layer (130) made of oxide semiconductor material is reduced, and the bonding between metal and oxygen is increased, so that the device can be stabilized and the reliability can be increased.

According to one embodiment of the present disclosure, when a direction parallel to a shortest line connecting a first connecting portion (130a) and a second connecting portion (130b) is referred to as a first direction (X), the length of a channel portion (130n) along the first direction (X) may be defined as the length of the channel portion, and when a direction perpendicular to the first direction (X) is referred to as a second direction (Y), the width of the channel portion (130n) along the second direction (Y) may be defined as the width of the channel portion.

In general, when the channel portion (130n) has a large width, when the connecting portion (130a) and the second connecting portion (130b) undergo conductorization, the interface between the channel portion (130n) and the conductive portion increases, so that the conductorization diffusion toward the channel portion (130n) may progress significantly. When the conductorization diffusion toward the channel portion (130n) progresses significantly, the threshold voltage (Vth) of the thin film transistor (100) may move in the negative (−) direction, so that the operating stability of the thin film transistor (100) may deteriorate.

According to one embodiment of the present disclosure, at least a portion of the first capture pattern (175a) and at least a portion of the second capture pattern (175b) may overlap the gate electrode (150) in a plan view.

Referring to FIG. 1, the first capture pattern (175a) and the second capture pattern (175b) may partially overlap with the gate electrode (150) in a planar view.

According to one embodiment of the present disclosure, at least a portion of the first capture pattern (175a) may overlap with the first connecting portion (130a) in a plan view. In addition, at least a portion of the second capture pattern (175b) may overlap with the second connecting portion (130b) in a plan view.

Referring to FIG. 1, the first capture pattern (175a) can overlap the gate electrode (150) and the first connecting portion (130a) simultaneously in a plan view, and the second capture pattern (175b) can overlap the gate electrode (150) and the second connecting portion (130b) simultaneously.

For example, the first capture pattern (175a) may be disposed from the gate electrode (150) toward the first connecting portion (130a) in a plane, and the second capture pattern (175b) may be disposed from the gate electrode (150) toward the second connecting portion (130b) in a plane.

When the first capture pattern (175a) and the second capture pattern (175b) are respectively disposed at the boundaries of one side and the other side of the gate electrode (150), the hydrogen concentration in the active layer (130) overlapping the first capture pattern (175a) and the second capture pattern (175b) can be reduced.

That is, when the hydrogen concentration in the active layer (130) overlapping the first capture pattern (175a) and the second capture pattern (175b) decreases, the conductorization diffusion can be suppressed in some areas of the boundary between the channel portion (130n) and the first connecting portion (130a) and the boundary between the channel portion (130n) and the second connecting portion (130b).

As a result, the threshold voltage (Vth) of the thin film transistor (100) can be prevented or suppressed from shifting in the negative (−) direction, and the reliability of the thin film transistor (100) can be improved.

According to one embodiment of the present disclosure, the thickness of the region in which the first capture pattern (175a) or the second capture pattern (175b) of the hydrogen capture layer (175) is disposed may be thinner than the thickness of the region in which the first capture pattern (175a) and the second capture pattern (175b) of the hydrogen capture layer (175) are not disposed.

FIG. 3 illustrates that the thickness of the region where the first capture pattern (175a) or the second capture pattern (175b) is disposed in the hydrogen capture layer (175) is thinner than the thickness of the region where the first capture pattern (175a) and the second capture pattern (175b) are not disposed.

According to one embodiment of the present disclosure, the first capture pattern (175a) and the second capture pattern (175b) each include a first sub-capture pattern (175a1, 175b1 ) and a second sub-capture pattern (175a2, 175b2) that are spaced apart from each other.

Specifically, the first capture pattern (175a) may include a first sub-capture pattern (175a1 ) and a second sub-capture pattern (175a2) that are spaced apart from each other. Although FIG. 1 illustrates that the first capture pattern (175a) includes a first sub-capture pattern (175a1 ) and a second sub-capture pattern (175a2), the present disclosure is not limited thereto, and may further include a third sub-capture pattern (not shown), a fourth sub-capture pattern (not shown), or may include more than that.

In addition, the second capture pattern (175b) may include a first sub-capture pattern (175b1) and a second sub-capture pattern (175b2) that are spaced apart from each other. Although FIG. 1 illustrates that the second capture pattern (175b) includes a first sub-capture pattern (175b1) and a second sub-capture pattern (175b2), the present disclosure is not limited thereto, and may further include a third sub-capture pattern (not shown), a fourth sub-capture pattern (not shown), or may include more than that.

In FIG. 1, the first sub-capture pattern (175a1, 175b1) and the second sub-capture pattern (175a2, 175b2) are each illustrated as having a rectangular shape, but the present disclosure is not limited thereto and may have a polygonal, circular, elliptical, or fan-shaped shape.

According to one embodiment of the present disclosure, the thin film transistor (100) may further include an insulating film (181) disposed on the hydrogen capture layer (175).

Referring to FIGS. 2 and 3, the hydrogen capture layer (175) may be disposed between the active layer (130) and the insulating film (181). For example, the insulating film (181) may be disposed within the first capture pattern (175a) and the second capture pattern (175b). For example, the insulating film (181) may be in direct contact with the first capture pattern (175a) and the second capture pattern (175b).

According to one embodiment of the present disclosure, the insulating film (181) may include at least one of silicon nitride (SiNx), silicon oxide (SiO₂), and aluminum oxide (Al₂O₃).

The hydrogen capture layer (175) can block or capture hydrogen that penetrates or diffuses through the insulating film (181) or a layer disposed on the insulating film (181).

According to one embodiment of the present disclosure, the thin film transistor (100) may include a source electrode (161) and a drain electrode (162) disposed on an insulating film (181). The positions of the source electrode (161) and the drain electrode (162) may be exchanged. However, one embodiment of the present disclosure is not limited thereto, and the first connecting portion (130a) and the second connecting portion (130b) may each function as a source electrode and a drain electrode.

Referring to FIGS. 1 to 3, the source electrode (161) and the drain electrode (162) may be connected to the active layer (130) through a contact hole, respectively. Specifically, the source electrode (161) may be in contact with the first connecting portion (130a) through the contact hole. The drain electrode (162) may be spaced apart from the source electrode (161) and may be in contact with the second connecting portion (130b) through the contact hole.

The light blocking layer (111) can be electrically connected to either the source electrode (161) or the drain electrode (162). FIGS. 1 to 3 illustrate a configuration in which the light blocking layer (111) is electrically connected to the source electrode (161).

The source electrode (161) and the drain electrode (162) may each include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The source electrode (161) and the drain electrode (162) may each have a multilayer film structure including at least two conductive films having different physical properties.

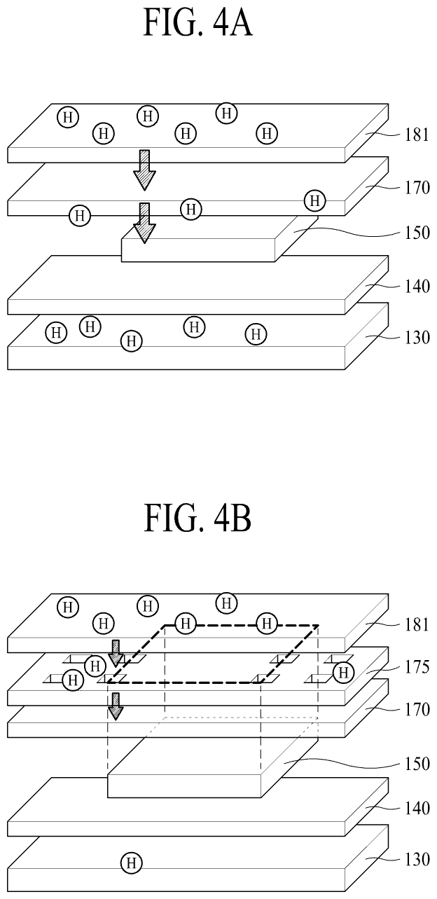

FIGS. 4A and 4B are exploded perspective views of thin film transistors according to comparative examples and embodiments.

FIG. 4a is an exploded perspective view of a thin film transistor according to a comparative example, and FIG. 4b is an exploded perspective view of a thin film transistor according to an embodiment.

Referring to FIG. 4a, a thin film transistor according to a comparative example may include an active layer (130), a gate insulating film (140) on the active layer (130), a gate electrode (150) on the gate insulating film (140), an interlayer insulating film (170) on the gate electrode (150), and an insulating film (181) on the interlayer insulating film (170).

Referring to FIG. 4b, the thin film transistor according to the embodiment may further include a hydrogen capture layer (175) disposed between the interlayer insulating film (170) and the insulating film (181) compared to the thin film transistor according to the comparative example.

FIG. 4b shows a thin film transistor according to an embodiment that further includes a hydrogen capture layer (175) so that hydrogen diffusion from the upper portion of the active layer (130) to the active layer (130) is reduced.

On the other hand, FIG. 4a shows that hydrogen permeates or diffuses from the upper part of the active layer (130) to the active layer (130) because the thin film transistor according to the comparative example does not include a hydrogen capture layer (175).

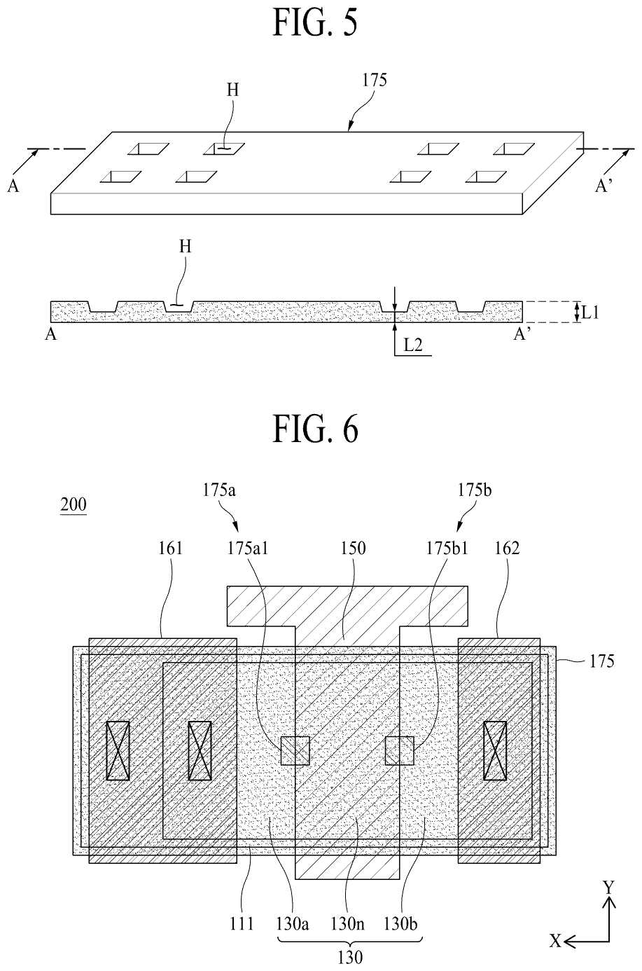

FIG. 5 is a drawing showing the appearance of the hydrogen capture layer (175) of the present disclosure.

FIG. 5 is a drawing showing a plan view of a hydrogen capture layer (175) and a cross-sectional view of the hydrogen capture layer (175) taken along line A-A′.

According to one embodiment of the present disclosure, the thickness of the region in which the first capture pattern (175a) or the second capture pattern (175b) of the hydrogen capture layer (175) is disposed may be thinner than the thickness of the region in which the first capture pattern (175a) and the second capture pattern (175b) of the hydrogen capture layer (175) are not disposed.

FIG. 5 illustrates a capture pattern (H) formed within a hydrogen capture layer (175), and the capture pattern (H) illustrated in FIG. 5 corresponds to the first capture pattern (175a) or the second capture pattern (175b) illustrated in FIGS. 1 to 3.

According to one embodiment of the present disclosure, when the thickness of the region (second region) where the first capture pattern (175a) or the second capture pattern (175b) of the hydrogen capture layer (175) is not disposed is L1, and the thickness of the region (first region) where the first capture pattern (175a) and the second capture pattern (175b) of the hydrogen capture layer (175) are disposed is L2, L1 may be 10 nm or less, and L2 may be 20% to 60% of L1. For example, the thickness (L1) of the second region may be 10 nm or less, and the thickness (L2) of the first region may be 20% to 60% of the thickness (L1) of the second region.

For example, if L1 exceeds 10 nm, the electron concentration in the hydrogen capture layer (175) may increase. This may cause a problem in which some of the hydrogen capture layer (175) acts as a channel. Therefore, in order to prevent the electron concentration in the hydrogen capture layer (175) from increasing, the thickness of L1 needs to be maintained at 10 nm or less.

When L2 is less than 20% compared to L1, a problem of over etching may occur to form the first capture pattern (175a) or the second capture pattern (175b).

In addition, when L2 exceeds 60% compared to L1, the surface area of the first capture pattern (175a) or the second capture pattern (175b) may decrease, thereby reducing hydrogen traps that may exist on the surface of the first capture pattern (175a) or the second capture pattern (175b). As a result, the ability of the first capture pattern (175a) and the second capture pattern (175b) to block or capture hydrogen may be reduced.

According to one embodiment of the present disclosure, when a direction parallel to a shortest line connecting the first connecting portion (130a) and the second connecting portion (130b) is referred to as a first direction (X), and a direction perpendicular to the first direction (X) is referred to as a second direction (Y), the first capture pattern (175a) and the second capture pattern (175b) may each have a width of 2 μm or more based on the second direction (Y).

For example, when the first capture pattern (175a) and the second capture pattern (175b) each include a first sub-capture pattern (175a1, 175b1) and a second sub-capture pattern (175a2, 175b2), each of the first sub-capture pattern (175a1, 175b1) and the second sub-capture pattern (175a2, 175b2) may have a width of 2 μm or more with respect to the second direction (Y).

In FIG. 1, when the width of the second capture pattern (175b) in the second direction (Y) is L3, L3 may be 2 μm or more. Specifically, in FIG. 1, the width of the first sub-capture pattern (175b1) may be 2 μm or more.

Although FIG. 1 illustrates that the width of the second capture pattern (175b) is L3, the same applies to the first capture pattern (175a).

On the other hand, when the first capture pattern (175a) and the second capture pattern (175b) have a width of less than 2 μm based on the second direction (Y), the surface area of the first capture pattern (175a) and the second capture pattern (175b) may decrease, thereby reducing hydrogen traps that bind to hydrogen. As a result, the hydrogen capturing ability of the hydrogen capture layer (175) may decrease.

Therefore, the first capture pattern (175a) and the second capture pattern (175b) need to have a width of 2 μm or more based on the second direction (Y).

According to one embodiment of the present disclosure, the first sub-capture pattern (175a1) and the second sub-capture pattern (175a2) of the first capture pattern (175a) may have a gap of 2 μm or more based on the second direction (Y). In addition, the first sub-capture pattern (175b1) and the second sub-capture pattern (175b2) of the second capture pattern (175b) may have a gap of 2 μm or more based on the second direction (Y).

In FIG. 1, when the gap between the first sub-capture pattern (175b1) and the second sub-capture pattern (175b2) of the second capture pattern (175b) in the second direction (Y) is L4, L4 may be 2 μm or more. Specifically, according to FIG. 1, the gap between the first sub-capture pattern (175b1) and the second sub-capture pattern (175b2) may be 2 μm or more.

Although FIG. 1 illustrates that the gap between the first sub-capture pattern (175b1) and the second sub-capture pattern (175b2) of the second capture pattern (175b) is L4, the same applies to the first capture pattern (175a).

On the other hand, when the first sub-capture pattern (175a1, 175b1) and the second sub-capture pattern (175a2, 175b2) have a gap of less than 2 μm with respect to the second direction (Y), hydrogen penetration into the active layer (130) may be excessively blocked, and thus the conductivity of the first connecting portion (130a) and the second connecting portion (130b) may be excessively reduced. As a result, a problem of excessively lowering the mobility of the thin film transistor according to the present disclosure may occur.

Therefore, the first sub-capture pattern (175a1, 175b1) and the second sub-capture pattern (175a2, 175b2) need to have a gap of 2 μm or more based on the second direction (Y).

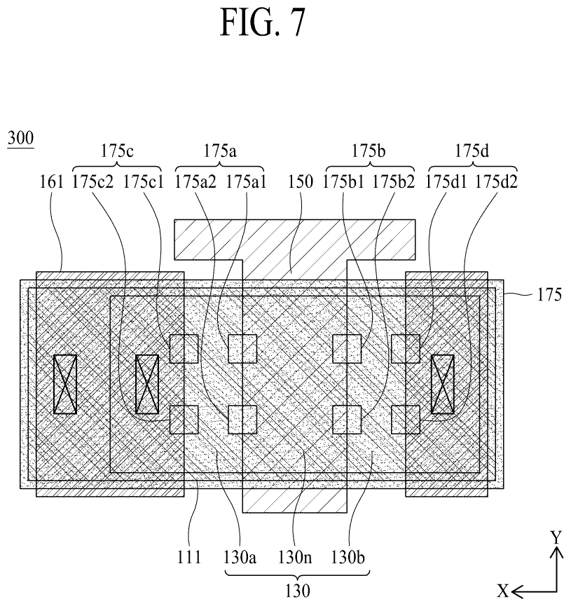

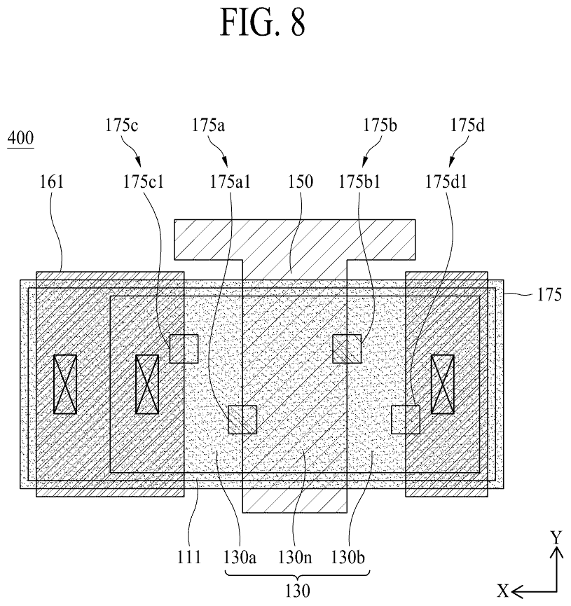

FIG. 6 is a plan view of a thin film transistor (200) according to another embodiment of the present disclosure. FIG. 7 is a plan view of a thin film transistor (300) according to another embodiment of the present disclosure. FIG. 8 is a plan view of a thin film transistor (400) according to another embodiment of the present disclosure.

Referring to FIG. 6, a thin film transistor (200) according to one embodiment of the present disclosure includes a first capture pattern (175a) and a second capture pattern (175b), and the first capture pattern (175a) and the second capture pattern (175b) may each include a first sub-capture pattern (175a1, 175b1).

The thin film transistor (200) of FIG. 6 may not include a second sub-capture pattern (175a2, 175b2) compared to the thin film transistor (100) of FIG. 1.

The description of the remaining components of the thin film transistor (200) illustrated in FIG. 6 is omitted as it overlaps with the description of the components of the thin film transistor (100) illustrated in FIG. 1.

According to one embodiment of the present disclosure, the hydrogen capture layer (175) may further include a third capture pattern (175c) and a fourth capture pattern (175d) that do not overlap the gate electrode (150) in a plan view.

FIG. 7 illustrates a hydrogen capture layer (175) further including a third capture pattern (175c) and a fourth capture pattern (175d) that do not overlap the gate electrode (150) in a plan view.

According to one embodiment of the present disclosure, the third capture pattern (175c) is disposed closer to the first connecting portion (130a) than to the second connecting portion (130b) in a plan view, and the fourth capture pattern (175d) is disposed closer to the second connecting portion (130b) than to the first connecting portion (130a) in a plan view. Specifically, the third capture pattern (175c) is disposed to overlap the first connecting portion (130a) in a plane, and the fourth capture pattern (175d) is disposed to overlap the second connecting portion (130b) in a plane.

Except that the third capture pattern (175c) and the fourth capture pattern (175d) do not overlap in a plane with the gate electrode (150), the description of the width, gap, and thickness of the third capture pattern (175c) and the fourth capture pattern (175d) overlaps with the description of the width, gap, and thickness of the first capture pattern (175a) and the second capture pattern (175b).

The third capture pattern (175c) and the fourth capture pattern (175d) may include first sub-capture patterns (175c1, 175d1) and second sub-capture patterns (175c2, 175d2) that are spaced apart from each other, similar to the first capture pattern (175a) and the second capture pattern (175b).

The description of the remaining components of the thin film transistor (300) illustrated in FIG. 7 is omitted as it overlaps with the description of the components of the thin film transistor (100) illustrated in FIG. 1.

Referring to FIG. 8, a thin film transistor (400) according to one embodiment of the present disclosure includes a first capture pattern (175a), a second capture pattern (175b), a third capture pattern (175c), and a fourth capture pattern (175d), and the first capture pattern (175a), the second capture pattern (175b), the third capture pattern (175c), and the fourth capture pattern (175d) may each include a first sub-capture pattern (175a1, 175b1, 175c1, 175d1).

The thin film transistor (400) of FIG. 8 may not include the second sub-capture pattern (175a2, 175b2, 175c2, 175d2) compared to the thin film transistor (300) of FIG. 7.

For example, the first sub-capture patterns (175a1, 175b1, 175c1, 175d1) illustrated in FIG. 8 may be disposed in a zigzag shape. For example, the first sub-capture patterns (175a1, 175b1) illustrated in FIG. 8 may be disposed spaced apart from each other with respect to the second direction (Y). For example, any straight line passing through the first sub-capture pattern (175a1) and parallel to the first direction (Y) may not pass through the first sub-capture pattern (175b1). However, one embodiment of the present disclosure is not limited thereto. For example, any straight line passing through the first sub-capture pattern (175a1) and parallel to the first direction (Y) may pass through the first sub-capture pattern (175b1) (see FIG. 6).

The description of the remaining components of the thin film transistor (400) illustrated in FIG. 8 is omitted as it overlaps with the description of the components of the thin film transistor (100) illustrated in FIG. 1.

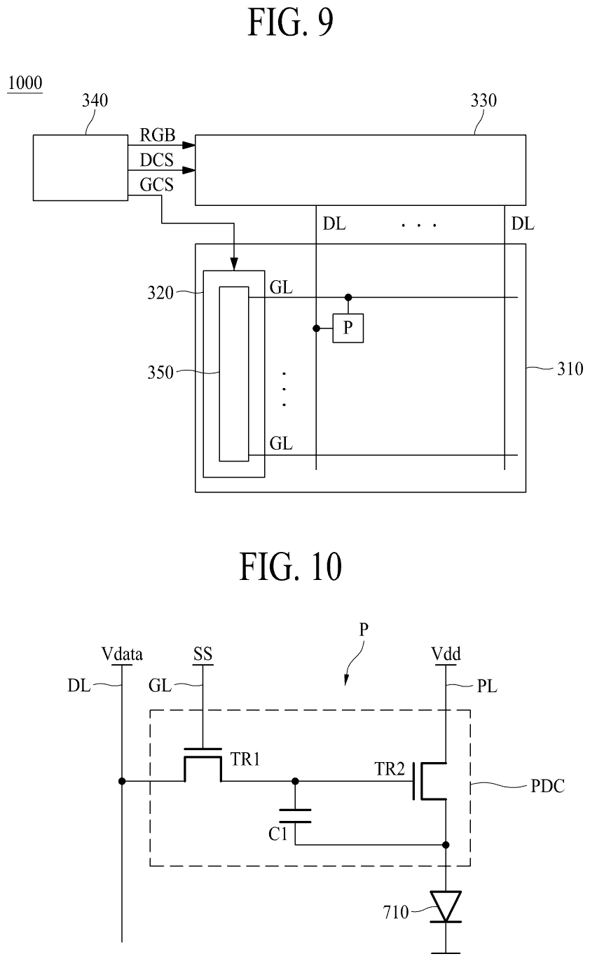

FIG. 9 is a schematic diagram of a display apparatus (1000) according to another embodiment of the present disclosure.

A display apparatus (1000) according to another embodiment of the present disclosure may include a display panel (310), a gate driver (320), a data driver (330), and a control unit (340), as illustrated in FIG. 9.

The display panel (310) includes gate lines (GL) and data lines (DL), and pixels (P) are disposed at intersections of the gate lines (GL) and data lines (DL). An image is displayed by driving the pixels (P). The gate lines (GL), data lines (DL), and pixels (P) may be disposed on a base substrate (110).

The control unit (340) controls the gate driver (320) and the data driver (330).

The control unit (340) outputs a gate control signal (GCS) for controlling the gate driver (320) and a data control signal (DCS) for controlling the data driver (330) using a signal supplied from an external system (not shown). In addition, the control unit (340) samples input image data input from an external system, rearranges it, and supplies redisposed digital image data (RGB) to the data driver (330).

The gate control signal (GCS) includes a gate start pulse (GSP), a gate shift clock (GSC), a gate output enable signal (GOE), a start signal (Vst), and a gate clock (GCLK). In addition, the gate control signal (GCS) may include control signals for controlling a shift register.

Data control signals (DCS) include source start pulse (SSP), source shift clock signal (SSC), source output enable signal (SOE), and polarity control signal (POL).

The data driver (330) supplies data voltage to the data lines (DL) of the display panel (310). Specifically, the data driver (330) converts image data (RGB) input from the control unit (340) into analog data voltage and supplies the data voltage to the data lines (DL).

According to one embodiment of the present disclosure, the gate driver (320) may be mounted on the display panel (310). In this way, a structure in which the gate driver (320) is directly mounted on the display panel (310) is called a Gate In Panel (GIP) structure. Specifically, in the Gate In Panel (GIP) structure, the gate driver (320) may be disposed on the base substrate (110).

The display apparatus (1000) according to one embodiment of the present disclosure may include the thin film transistor (100, 200, 300, 400) described above. According to one embodiment of the present disclosure, a gate driver (320) may include the thin film transistor (100, 200, 300, 400) described above.

The gate driver (320) may include a shift register (350).

The shift register (350) sequentially supplies gate pulses to the gate lines (GL) for one frame using a start signal and a gate clock transmitted from the control unit (340). Here, one frame refers to a period during which one image is output through the display panel (310). The gate pulse has a turn-on voltage capable of turning on a switching element (thin film transistor) disposed in a pixel (P).

In addition, the shift register (350) supplies a gate off signal capable of turning off the switching element to the gate line (GL) during the remaining period when the gate pulse is not supplied during one frame. Hereinafter, the gate pulse and the gate off signal are collectively referred to as a scan signal (SS or Scan).

The shift register (350) may include the thin film transistor (100, 200, 300, 400) described above.

FIG. 10 is a circuit diagram for one pixel (P) of FIG. 9.

The circuit diagram of FIG. 10 is an equivalent circuit diagram for a pixel (P) of a display apparatus (1000) including an organic light-emitting diode (OLED) as a display element (710).

Referring to FIG. 10, a pixel (P) includes a display element (710) and a pixel driving circuit (PDC) that drives the display element (710). Specifically, a display apparatus (1000) according to one embodiment of the present disclosure may include a pixel driving circuit (PDC) on a base substrate (110).

The pixel driving circuit (PDC) of FIG. 10 includes a first thin film transistor (TR1) which is a switching transistor and a second thin film transistor (TR2) which is a driving transistor. A display apparatus (1000) according to another embodiment of the present disclosure may include at least one of the thin film transistors (100, 200, 300, 400).

The first thin film transistor (TR1) is connected to the gate line (GL) and the data line (DL), and is turned on or off by the scan signal (SS) supplied through the gate line (GL).

The data line (DL) provides a data voltage (Vdata) to the pixel driver circuit (PDC), and the first thin film transistor (TR1) controls the application of the data voltage (Vdata).

The driving power line (PL) provides a driving voltage (Vdd) to the display element (710), and the first thin film transistor (TR1) controls the driving voltage (Vdd). The driving voltage (Vdd) is a pixel driving voltage for driving the organic light-emitting diode (OLED), which is the display element (710).

When the first thin film transistor (TR1) is turned on by a scan signal (SS) applied through the gate line (GL) from the gate driver (320), the data voltage (Vdata) supplied through the data line (DL) is supplied to the gate electrode of the second thin film transistor (TR2) connected to the display element (710). The data voltage (Vdata) is charged in the storage capacitor (Cst) formed between the gate electrode and the source electrode of the second thin film transistor (TR2).

The amount of current supplied to the organic light-emitting diode (OLED), which is a display element (710), through the second thin film transistor (TR2) is controlled according to the data voltage (Vdata), and accordingly, the gradation of light output from the display element (710) can be controlled.

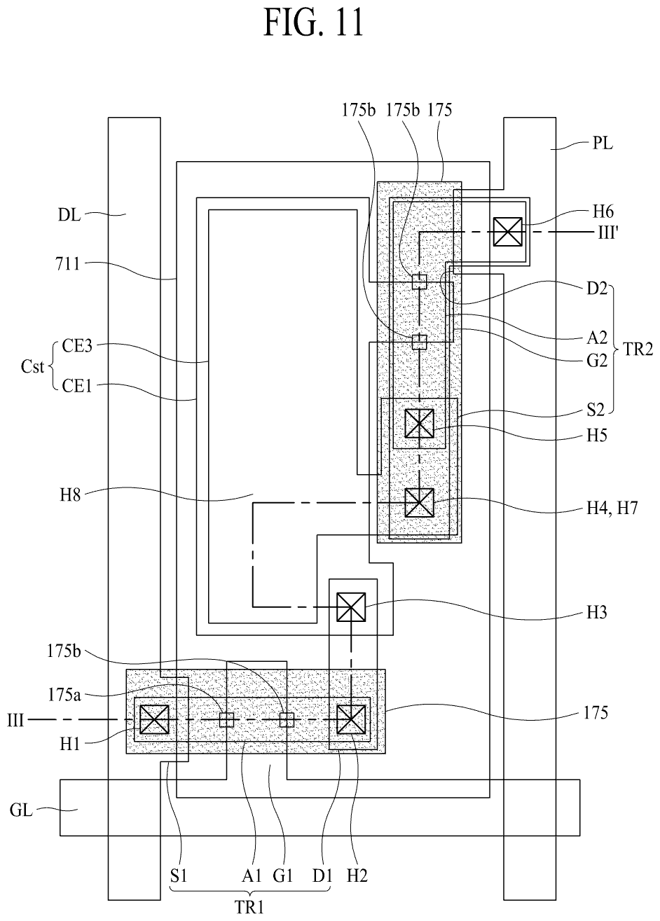

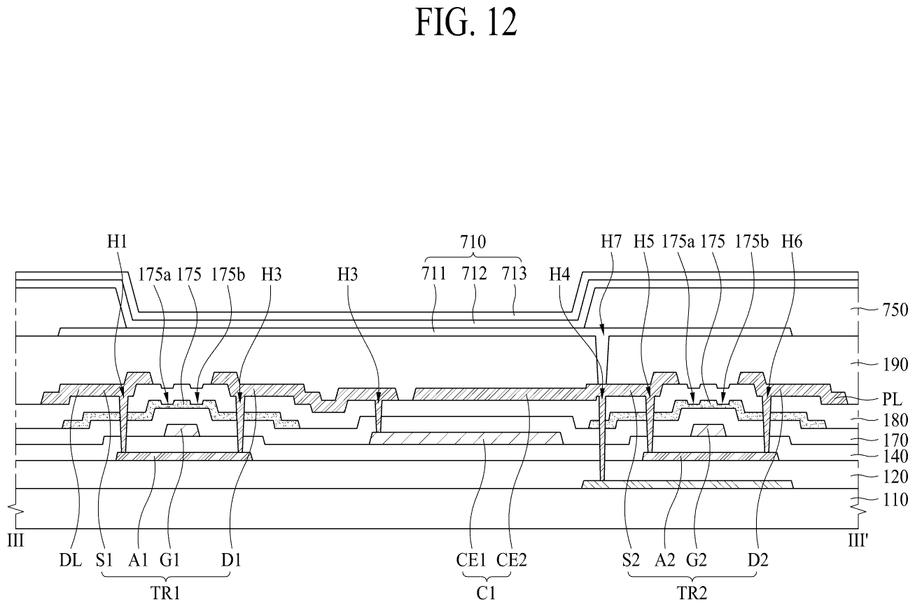

FIG. 11 is a plan view of the pixel of FIG. 10, and FIG. 12 is a cross-sectional view taken along line III-III′ of FIG. 11.

Referring to FIGS. 11 and 12, a first thin film transistor (TR1) and a second thin film transistor (TR2) are disposed on a base substrate (110).

The base substrate (110) may be made of glass or plastic. As the base substrate (110), a plastic having flexible properties, for example, polyimide (PI), may be used.

A light-blocking layer (111) is disposed on a base substrate (110). The light-blocking layer (111) may have light-blocking properties. The light-blocking layer (111) may block light incident from the outside to protect the active layers (A1, A2). FIGS. 11 and 12 illustrate a configuration in which the light-blocking layer (111) is disposed under the active layer (A2) of the second thin film transistor (TR2).

A buffer layer (120) is disposed on the light blocking layer (111). The buffer layer (120) is made of an insulating material and protects the active layers (A1, A2) from moisture or oxygen flowing in from the outside.

The first active layer (A1) of a first thin film transistor (TR1) and the second active layer (A2) of a second thin film transistor (TR2) are disposed on a buffer layer (120).

The first active layer (A1) and the second active layer (A2) may include, for example, an oxide semiconductor material. The first active layer (A1) and the second active layer (A2) may be formed of an oxide semiconductor layer made of an oxide semiconductor material.

In the first thin film transistor (TR1), the first active layer (A1) may include a channel portion, a first connecting portion, and a second connecting portion. The channel portion of the first active layer (A1) overlaps the gate electrode (G1). According to another embodiment of the present disclosure, the first connecting portion may be referred to as a source electrode (S1), and the second connecting portion may be referred to as a drain electrode (D1).

In the second thin film transistor (TR2), the second active layer (A2) may include a channel portion, a first connecting portion, and a second connecting portion. The channel portion of the second active layer (A2) overlaps the gate electrode (G2). According to another embodiment of the present disclosure, the first connecting portion may be referred to as a source electrode (S2), and the second connecting portion may be referred to as a drain electrode (D2).

A gate insulating film (140) is disposed on the active layer (A1, A2). The gate insulating film (140) covers the upper surface of the active layer (A1, A2).

A gate electrode (G1) of a first thin film transistor (TR1) and a gate electrode (G2) of a second thin film transistor (TR2) are disposed on a gate insulating film (140).

Although not shown in the drawing, a gate line (GL) may be disposed on the gate insulating film (140). The gate electrode (G1) of the first thin film transistor (TR1) may extend from the gate line (GL) or may be a part of the gate line (GL).

Referring to FIGS. 10 and 11, a first capacitor electrode (CE1) of a storage capacitor (Cst) is formed on a gate insulating film (140). The first capacitor electrode (CE1) can be formed using the same material as the gate electrodes (G1, G2) through the same process.

An interlayer insulating film (170) is disposed on the gate electrodes (G1, G2) and the first capacitor electrode (CE1).

A hydrogen capture layer (175) is disposed on the interlayer insulating film (170).

The hydrogen capture layer (175) may include any one of an IGZO (InGaZnO)-based oxide semiconductor material in which the concentration of Ga is 40% or more relative to the total concentration of In, Ga, and Zn based on the number of atoms, a GO (GaO)-based oxide semiconductor material, a GZO (GaZnO)-based oxide semiconductor material, and silicon oxide (SiO₂).

The hydrogen capture layer (175) includes a first capture pattern (175a) and a second capture pattern (175b). The first capture pattern (175a) and the second capture pattern (175b) are spaced apart from each other with a gate electrode (G1, G2) interposed therebetween in a plan view.

An insulating film (181) is disposed on the hydrogen capture layer (175). The insulating film (181) may include at least one of silicon nitride (SiNx), silicon oxide (SiO₂), and aluminum oxide (Al₂O₃).

The hydrogen capture layer (175) can block or capture hydrogen that penetrates or diffuses through the insulating film (181) or a layer disposed on the insulating film (181).

A data line (DL) and a driving power line (PL) are disposed on an insulating film (181). In addition, a source electrode (S1) and a drain electrode (D1) of a first thin film transistor (TR1) are disposed on an interlayer insulating film (170), and a source electrode (S2) and a drain electrode (D2) of a second thin film transistor (TR2) are disposed.

The source electrode (S1) of the first thin film transistor (TR1) may be formed integrally with the data line (DL) and may have a structure extending from the data line (DL).

The source electrode (S1) of the first thin film transistor (TR1) can contact the side of the active layer (A1) of the first thin film transistor (TR1) through the first contact hole (H1).

The drain electrode (D1) of the first thin film transistor (TR1) contacts the other side of the active layer (A1) of the first thin film transistor (TR1) through the second contact hole (H2). In addition, the drain electrode (D1) of the first thin film transistor (TR1) is connected to the first capacitor electrode (CE1) through the third contact hole (H3). As a result, the first capacitor electrode (CE1) can be connected to the first thin film transistor (TR1).

The drain electrode (D2) of the second thin film transistor (TR1) may be formed integrally with the driving power line (PL) and may have a structure extending from the driving power line (PL).

The drain electrode (D2) of the second thin film transistor (TR1) can contact the side of the active layer (A2) of the second thin film transistor (TR2) through the sixth contact hole (H6).

The source electrode (S2) of the second thin film transistor (TR2) contacts the other side of the active layer (A2) of the second thin film transistor (TR2) through the fifth contact hole (H5). In addition, the source electrode (S2) of the second thin film transistor (TR2) is connected to the light-blocking layer (111) through the fourth contact hole (H4). The same voltage as the source electrode (S2) of the second thin film transistor (TR2) can be applied to the light-blocking layer (111) overlapping the second thin film transistor (TR2).

The source electrode (S2) of the second thin film transistor (TR2) can extend onto the insulating film (181) to form a second capacitor electrode (CE2) of the storage capacitor (Cst).

According to one embodiment of the present disclosure, a first capacitor electrode (CE1) and a second capacitor electrode (CE2) may overlap to form a storage capacitor (Cst).

Referring to FIGS. 11 and 12, a planarization layer (190) is disposed on the data line (DL), the driving power line (PL), the source electrodes (S1, S2), the drain electrodes (D1, D2), and the second capacitor electrode (CE2). The planarization layer (190) planarizes the upper portions of the first thin film transistor (TR1) and the second thin film transistor (TR2), and protects the first thin film transistor (TR1) and the second thin film transistor (TR2). The planarization layer (190) functions as a protective layer.

A first electrode (711) of a display element (710) is disposed on a planarization layer (190). The first electrode (711) of the display element (710) contacts a second capacitor electrode (CE2) through a seventh contact hole (H7) formed in the planarization layer (180). As a result, the first electrode (711) of the display element (710) can be connected to a source electrode (S2) of a second thin film transistor (TR2).

A bank layer (750) is disposed at the edge of the first electrode (711). The bank layer (750) defines a light-emitting area of the display element (710).

An organic light-emitting layer (712) is disposed on a first electrode (711), and a second electrode (713) is disposed on the organic light-emitting layer (712). Accordingly, a display element (710) is completed. The display element (710) illustrated in FIG. 21 is an organic light-emitting diode (OLED). Therefore, a display apparatus (1000) according to an embodiment of the present disclosure is an organic light-emitting display apparatus.

A pixel driving circuit (PDC) according to another embodiment of the present disclosure may be formed in various structures other than the structures described above. The pixel driving circuit (PDC) may include, for example, five or more thin film transistors.

According to the present disclosure, the following advantageous effects may be obtained.

A thin film transistor according to one embodiment of the present disclosure has a hydrogen capture layer including a large number of traps capable of trapping hydrogen, thereby suppressing or preventing hydrogen from diffusing into an active layer.

A thin film transistor according to one embodiment of the present disclosure has a hydrogen capture layer including a large number of traps capable of trapping hydrogen, thereby controlling conductorization penetration into a channel portion.

A thin film transistor according to one embodiment of the present disclosure can have excellent reliability by having a hydrogen capture layer including a large number of traps capable of trapping hydrogen.

As used herein, the term “micro-patterned cavity” refers to a recessed region formed in a sheet of oxide-based semiconductor material, such as a hydrogen capture layer, by a patterned etching process. Each micro-patterned cavity may be formed by selectively etching the oxide-based material using a wet or dry etchant, creating a groove-like structure having a reduced thickness relative to adjacent, unetched portions of the layer.

The micro-patterned cavity includes one or more sidewalls and a base surface, and may exhibit increased surface roughness and defect density as a result of the etching process. This increased surface area and structural irregularity enhance the layer's ability to adsorb, trap, or chemically bind diffusing hydrogen species, thereby suppressing hydrogen penetration into an underlying active layer of a thin film transistor.

The micro-patterned cavities may be disposed to overlap the boundaries between the transistor's channel region and source/drain (connecting) regions, or may be offset laterally, depending on the configuration. In various embodiments, the cavity may have a rectangular, polygonal, or curved cross-sectional profile, and may be repeated in a symmetric or asymmetric pattern across the layer.

Additional embodiments of the present disclosure include the following.

In one embodiment, a display apparatus comprises a light-emitting diode (LED) and a thin film transistor (TFT) that is electrically connected to the LED. The thin film transistor 100 may include an active layer 130 formed on a substrate 110, wherein the active layer 130 comprises a channel portion 130n positioned between a first connecting portion 130a and a second connecting portion 130b. A gate insulating film 140 is disposed on the active layer 130, and a gate electrode 150 is disposed on the gate insulating film 140 so as to overlap at least a portion of the channel region in a plan view. An interlayer insulating film 170 may be formed over the gate electrode 150.

Further, at least one sheet of oxide-based semiconductor material 175 is disposed on the interlayer insulating film 170. This sheet 175 may serve as a hydrogen capture layer 175, and may include a plurality of recessed regions (e.g., a plurality of capture patterns) formed therein. Each recessed region has a reduced thickness relative to the adjacent, unrecessed portions of the sheet. In some embodiments, at least one recessed region is disposed, in a plan view, such that it at least partially overlaps both the first connecting portion 130a and the gate electrode 150. Similarly, at least one other recessed region may be disposed to at least partially overlap the second connecting portion 130b and the gate electrode 150.

The recessed regions may define hydrogen-trapping surfaces formed on the sidewalls and base of each recess. These hydrogen-trapping surfaces are configured to exhibit increased surface area and structural features conducive to binding or adsorbing hydrogen. In operation, such hydrogen-trapping surfaces serve to suppress or inhibit hydrogen diffusion into the underlying active layer, particularly at the boundaries between the channel portion and the adjacent first and second connecting portions. As a result, these structures mitigate undesired hydrogen-induced conductorization or instability within the transistor's channel region.

In some implementations, at least one pair of recessed regions may be symmetrically disposed on opposite lateral sides of the gate electrode 150, when viewed in plan view. Such symmetrical placement provides balanced hydrogen suppression effects at both interfaces of the channel region, improving uniformity in transistor characteristics and reducing asymmetric shifts in threshold voltage.

The at least one sheet of oxide-based semiconductor material 175 may be disposed in direct physical contact with the interlayer insulating film 170 (as shown in FIG. 3). This arrangement promotes simplified fabrication and efficient hydrogen capture by minimizing intervening material layers that might otherwise inhibit hydrogen diffusion into the recessed regions.

In some embodiments, the oxide-based semiconductor sheet has a nominal thickness L₁, and each recessed region may be formed by etching into the sheet to a depth (L₁-L₂), such that L₂ is 20% to 60% of L₁. This depth range is selected to ensure a balance between trap surface area (for hydrogen retention) and mechanical/electrical stability of the sheet.

The oxide-based semiconductor sheet may, in certain embodiments, comprise a multilayer stack that includes at least one layer of an oxide-based semiconductor (e.g., IGZO) and one or more additional layers, such as silicon oxide (SiO₂). The incorporation of silicon oxide may enhance hydrogen trapping capability or serve as a buffer or dielectric interface layer.

Each recessed region may have a width of at least 2 micrometers in a direction transverse to the current flow through the channel portion of the thin film transistor. This dimension is selected to ensure that a sufficient number of hydrogen traps are exposed to intercept diffusing hydrogen and prevent excessive conductorization of the active layer.

Each recessed region may define a micro-patterned cavity having one or more sidewalls and a base surface. These surfaces may exhibit increased surface roughness due to the etching or patterning process used to form the cavities. This roughness contributes to the formation of defect sites or adsorption sites that can chemically or physically bind hydrogen atoms or molecules.

In operation, the micro-patterned cavity of each recessed region functions to retain or immobilize hydrogen species that diffuse through upper layers of the device. This retention reduces the concentration of free hydrogen near the critical regions of the transistor, such as the channel-to-source/drain interfaces, thereby enhancing device reliability and threshold voltage stability.

In one embodiment, at least two recessed regions of the plurality are disposed on opposite sides of a longitudinal axis defined by the gate electrode. Such positioning facilitates symmetric suppression of hydrogen migration into the active layer on both sides of the channel region.

The hydrogen capture layer may comprise at least four recessed regions, including two recessed regions that overlap the connecting portions of the active layer, and two additional recessed regions that are adjacent to, but not overlapping, the gate electrode in plan view. This configuration provides both primary and secondary hydrogen capture zones to further reduce the risk of hydrogen diffusion reaching the channel region.

Each recessed region may have a substantially rectangular cross-section, as defined by a planar base and vertical or sloped sidewalls. Such geometry is conducive to consistent etch depths and predictable trap formation during fabrication, and may be formed using anisotropic etching techniques or a patterned resist mask.

In addition to the effects mentioned above, other features and advantages of the present disclosure are described below or may be clearly understood by those skilled in the art to which the present disclosure pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer;
a gate electrode disposed on the active layer and overlapping at least a portion of the active layer; and
a hydrogen capture layer disposed on the gate electrode,
wherein the active layer includes:
a channel portion;
a first connecting portion connected to one side of the channel portion; and
a second connecting portion connected to the other side of the channel portion,
wherein the hydrogen capture layer includes a first capture pattern and a second capture pattern that are spaced apart from each other, and
wherein at least a portion of the first capture pattern and at least a portion of the second capture pattern overlap the gate electrode in a plan view.

2. The thin film transistor of claim 1, wherein at least a portion of the first capture pattern overlaps the first connecting portion in a plan view, and at least a portion of the second capture pattern overlaps the second connecting portion in a plan view.

3. The thin film transistor of claim 1, wherein the hydrogen capture layer includes any one of an IGZO (InGaZnO)-based oxide semiconductor material, in which a concentration of Ga is 40% or more relative to the total concentration of In, Ga, and Zn based on the number of atoms, a GO (GaO)-based oxide semiconductor material, a GZO (GaZnO)-based oxide semiconductor material, and silicon oxide (SiO₂).

4. The thin film transistor of claim 1, wherein the first capture pattern and the second capture pattern are disposed in a groove of the hydrogen capture layer.

5. The thin film transistor of claim 1, wherein hydrogen traps that bind to hydrogen exist on the surfaces of the first capture pattern and the second capture pattern.

6. The thin film transistor of claim 1, wherein when a region of the hydrogen capture layer in which the first capture pattern or the second capture pattern is disposed is referred to as a first region, and a region of the hydrogen capture layer in which the first capture pattern or the second capture pattern is not disposed is referred to as a second region, and
wherein a thickness of the first region is thinner than a thickness of the second region.

7. The thin film transistor of claim 6, wherein the thickness of the second region is 10 nm or less, and the thickness of the first region is 20% to 60% of the thickness of the second region.

8. The thin film transistor of claim 1, wherein when a direction parallel to a shortest line connecting the first connecting portion and the second connecting portion is referred to as a first direction, and a direction perpendicular to the first direction is referred to as a second direction, the first capture pattern and the second capture pattern each have a width of 2 μm or more based on the second direction.

9. The thin film transistor of claim 1, further comprising an insulating film disposed on the hydrogen capture layer,
wherein the hydrogen capture layer is disposed between the active layer and the insulating film, and
wherein the insulating film is in contact with the first capture pattern and the second capture pattern.

10. The thin film transistor of claim 9, wherein the insulating film includes at least one of silicon nitride (SiNx), silicon oxide (SiO₂), and aluminum oxide (Al₂O₃).

11. The thin film transistor of claim 1, wherein the first capture pattern and the second capture pattern each includes a first sub-capture pattern and a second sub-capture pattern that are spaced apart from each other.

12. The thin film transistor of claim 11, wherein when a direction parallel to a shortest line connecting the first connecting portion and the second connecting portion is referred to as a first direction, and a direction perpendicular to the first direction is referred to as a second direction, the first sub-capture pattern and the second sub-capture pattern of the first capture pattern have a gap of 2 μm or more based on the second direction, and
wherein the first sub-capture pattern and the second sub-capture pattern of the second capture pattern have a gap of 2 μm or more based on the second direction.

13. The thin film transistor of claim 1, wherein the hydrogen capture layer further includes a third capture pattern and a fourth capture pattern that do not overlap the gate electrode in a plan view,
wherein the third capture pattern is disposed closer to the first connecting portion than to the second connecting portion, and
wherein the fourth capture pattern is disposed closer to the second connecting portion than to the first connecting portion.

14. The thin film transistor of claim 13, wherein the third capture pattern and the fourth capture pattern each includes a first sub-capture pattern and a second sub-capture pattern that are spaced apart from each other.

15. A display apparatus comprising:
a light-emitting diode;
a thin film transistor electrically connected to the light-emitting diode, the thin film transistor including:
an active layer on a substrate, the active layer having a channel portion between a first connecting portion and a second connecting portion;
a gate insulating film on the active layer;
a gate electrode on the gate insulating film and overlapping the channel region in a plan view;
an interlayer insulating film on the gate electrode; and
at least one sheet of oxide-based semiconductor material on the interlayer insulating film, the at least one sheet of oxide-based semiconductor material including a plurality of recessed regions, each recessed region having a reduced thickness relative to adjacent regions of the at least one sheet of oxide-based semiconductor material,
wherein, in plan view, at least one of the recessed regions is disposed to at least partially overlap the first connecting portion and the gate electrode, and at least one of the recessed regions is disposed to at least partially overlap the second connecting portion and the gate electrode.

16. The display apparatus of claim 15, wherein at least one pair of the recessed regions of the plurality is symmetrically disposed on opposite sides of the gate electrode.

17. The display apparatus of claim 15, wherein the at least one sheet of oxide-based semiconductor material is in direct contact with the interlayer insulating film.

18. The display apparatus of claim 15, wherein the at least one sheet of oxide-based semiconductor material has a thickness L₁,
wherein each recessed region extends into the sheet to depth (L₁-L₂), and
wherein L₂ is 20 % to 60 % of L₁.

19. The display apparatus of claim 15, wherein at least two recessed regions of the plurality are disposed on opposite sides of a longitudinal axis defined by the gate electrode.

20. The display apparatus of claim 15, wherein the at least one sheet of oxide-based semiconductor material comprises at least four recessed regions, including two that overlap the connecting portions and two that are located adjacent to but not overlapping the gate electrode, in plan view.
